(19) United States
(12) Patent Application Publication
(10) Pub. No.: US 2026/0239977 A1
(43) Pub. Date: Aug. 13, 2026

(54) SEMICONDUCTOR DEVICE

(71) Applicant: Minebea Power Semiconductor Device Inc., Ibaraki (JP)

(72) Inventors: Hitoshi NISHIMORI, Tokyo (JP); Norio NAKAZATO, Tokyo (JP); Takayuki KUSHIMA, Hitachi-shi (JP); Koji SASAKI, Hitachi-shi (JP)

(21) Appl. No.: 19/160,877

(22) PCT Filed: Oct. 10, 2023
(86) PCT No.: PCT/JP2023/036737

§ 371 Date: Aug. 29, 2025

(30) Foreign Application Priority Data
Mar. 6, 2023 (JP) 2023-033385

(51) Int. Cl. H10W 40/47; H10W 40/22

(52) U.S. Cl. CPC H10W 40/47; H10W 40/228

(57) ABSTRACT

Provided is a direct water-cooled semiconductor device in which a surface of a base plate opposite to a semiconductor element mounting surface is cooled by a coolant and which allows the flow path resistance of the coolant to be reduced and the deformation of a sealing part due to the coolant pressure to be suppressed. A direct water-cooled semiconductor device in which a surface of a base plate opposite to a semiconductor element mounting surface by a coolant includes the base plate, a semiconductor module mounted on a first surface of the base plate, and a pin fin and a plate-like fin mounted on a second surface of the base plate opposite to the first surface, and the length of the plate-like fin from the second surface is shorter than that of the pin fin from the second surface.

### TECHNICAL FIELD

The present invention relates to the structure of a semiconductor device, and more specifically, to a technology that is effectively applicable to a power semiconductor module formed by modularizing multiple power semiconductor elements.

### BACKGROUND ART

As a control device for a drive motor for a railway vehicle, there is a device (converter) that converts overhead line voltage from AC to DC or a device (inverter) that converts DC to AC using power semiconductor elements. Since power semiconductor elements generate heat due to conversion loss, the power semiconductor elements must be appropriately cooled to reduce the temperature rise. The cooling method is selected according to difference in load, such as high-speed vehicle operation and commuter train operation, and a water cooling system, which enables efficient cooling, may be used in the case of high-speed trains with a heavy load.

Indirect water cooling is generally used in conventional water cooling technology for a power semiconductor module including multiple power semiconductor elements, in which a heat sink with heat dissipation fins is typically attached to the power semiconductor module via, for example, thermal grease, and the heat dissipation fins are immersed in a cooling water path for heat dissipation. However, since the thermal grease has a lower thermal conductivity than metal, it has a high thermal resistance, which hinders the suppression of temperature rise.

Meanwhile, in order to ensure higher cooling capability, power semiconductor modules are known which use a direct water cooling method, and in this method, heat is transferred from power semiconductor elements to cooling water without through the thermal grease.

The direct water-cooled power semiconductor module has power semiconductor elements mounted on one surface of a base plate via an insulating layer and heat dissipation fins provided on the other surface. The direct water-cooled power semiconductor module is fixed to a water path-forming body using bolts, screws, or similar fasteners, and in this structure, the opening of the water path-forming body is covered and sealed by the heat dissipation fin-forming surface of a base plate, allowing the surface to be directly cooled by the cooling water, so that the module has the advantage of efficiently dissipating the heat generated by the power semiconductor elements.

Meanwhile, to increase the output of high-voltage inverters in railways and other high-system-voltage applications, the use of multiple parallel power semiconductor modules has become important. The use of multiple parallel power semiconductor modules has the effect of reducing current load per power semiconductor module and suppressing the temperature rise of the power semiconductor elements.

One of the background technologies in the technical field includes, for example, the technology disclosed in Patent Literature 1. Patent Literature 1 indicates that “the cooling structure of the power semiconductor element includes a chip 31 mounted on a mounting surface, a cooling water passage 26 formed to oppose the mounting surface and let cooling water flow to cool the chip 31, and fins 41 provided in the cooling water passage 26. The fin 41 has a straight fin portion 42 and a wave fin portion 43 arranged in different sections on the path of the cooling water passage 26. The straight fin portion 42 has a surface extending in the direction of the cooling water flow along the path of the cooling water passage 26. The wave fin portion 43 has a surface extending in a direction that crosses the cooling water flow direction along the path of the cooling water passage 26. The wave fin portion 43 is provided in a form that results in a higher heat transfer coefficient with the cooling water than the straight fin portion 42” (for example paragraph [0007] in Patent Literature 1).

### CITATION LIST

### Patent Literature

Patent Literature 1: Japanese Patent Application Publication No. 2007-201181

### SUMMARY OF INVENTION

### Technical Problem

In the configuration disclosed in Patent Literature 1, since the flow path is partitioned by the multiple straight fin portions 42 and wave fin portions 43, which increases the flow path resistance and makes the overall pressure loss of the flow path more likely to become large.

Further, in the configuration disclosed in Patent Literature 1, when the case body and the heat dissipation plate in the heat dissipation path for dissipating the heat generated by the power semiconductor elements are made thinner to reduce the thermal resistance, the deformation of the case body and the heat dissipation plate due to cooling water pressure loss increases, and as a result, when sealing is performed by screw fastening to prevent leakage of the coolant for water cooling, the sealed part farther from the screwed part tends to undergo greater deformation, which makes it necessary to prevent water leakage.

It is therefore an object of the present invention to provide a direct water-cooled semiconductor device in which a surface of a base plate opposite to a semiconductor element mounting surface is cooled by a coolant and which allows the flow path resistance of the coolant to be reduced and the deformation of the sealed part due to the coolant pressure to be suppressed.

### Solution to Problem

In order to solve the above problem, according to the present invention, there is provided a direct water-cooled semiconductor device in which a surface of a base plate opposite to a semiconductor element mounting surface is cooled by a coolant, the semiconductor device includes the base plate, a semiconductor module mounted on a first surface of the base plate, and a pin fin and a plate-like fin attached to a second surface of the base plate opposite to the first surface, and the plate-like fin has a length from the second surface which is shorter than that of the pin fin from the second surface.

### Advantageous Effects of Invention

According to the present invention, provided is a direct water-cooled semiconductor device in which a surface of a base plate opposite to a semiconductor element mounting surface is cooled by a coolant and which allows the flow path resistance of the coolant to be reduced and the deformation of a sealing part due to coolant pressure to be suppressed.

This makes it possible to improve the water pressure resistance by suppressing the deformation of the sealing part due to the coolant pressure caused by pressure loss, and improve the reliability of the semiconductor device. Furthermore, since the water pressure resistance is improved, the base plate can be made thinner, leading to improvement in the cooling efficiency of the semiconductor elements.

Problems, configurations, and advantageous effects other than those described above will become apparent from the following description of the embodiments.

### BRIEF DESCRIPTION OF DRAWINGS

FIG. 1 is a circuit diagram of a main power conversion power semiconductor module according to Embodiment 1 of the present invention.

FIG. 2 is a circuit diagram of a converter 4 in FIG. 1.

FIG. 3 is a circuit diagram of an inverter 5 in FIG. 1.

FIG. 4 is a diagram of the cooling system of a main power conversion device 10 shown in FIG. 1.

FIG. 5 is an external view of a power unit 53 in FIG. 4.

FIG. 6 is a circuit diagram of the power semiconductor module 100 in FIG. 5.

FIG. 7 is an external view of the power semiconductor module 100 in FIG. 5.

FIG. 8A is a side view as viewed from the B-B direction in FIG. 7.

FIG. 8B is a side view as viewed from the C-C direction in FIG. 7.

FIG. 9 is an exploded view of the power semiconductor module 100 in FIG. 5.

FIG. 10 is a plan view of the base plate of a power semiconductor module according to Embodiment 1 of the present invention as viewed from the side of the water path forming body.

FIG. 11 is an exploded perspective view of the power unit 53 in FIG. 5.

FIG. 12 is a view showing the flow direction of cooling water in the water path forming body 70 of the power unit 53 in FIG. 5.

FIG. 13 is a cross-sectional view taken along line A-A in FIG. 5.

FIG. 14 is a plan view of the base plate of a power semiconductor module according to Embodiment 2 of the present invention as viewed from the side of the water path forming body.

FIG. 15 is a side view of a power semiconductor module according to Embodiment 3 of the present invention.

FIG. 16 is a plan view of the base plate of a power semiconductor module according to Embodiment 4 of the present invention as viewed from the side of the water path forming body.

FIG. 17 is a plan view of the base plate of a power semiconductor module according to Embodiment 5 of the present invention as viewed from the side of the water path forming body.

FIG. 18 is a plan view of the base plate of a power semiconductor module according to Embodiment 6 of the present invention as viewed from the side of the water path forming body.

FIG. 19 is a cross-sectional view of a power semiconductor module according to Embodiment 7 and Embodiment 8 of the present invention.

FIG. 20 is a plan view of the base plate of a power semiconductor module according to Embodiment 9 of the present invention as viewed from the side of the water path forming body.

FIG. 21 is a plan view of the base plate of a power semiconductor module according to Embodiment 10 of the present invention as viewed from the side of the water path forming body.

### DESCRIPTION OF EMBODIMENTS

Embodiments of the present invention will be described with reference to the drawings. In the drawings, the same reference signs designate the same components, and detailed descriptions thereof will not be repeated.

### Embodiment 1

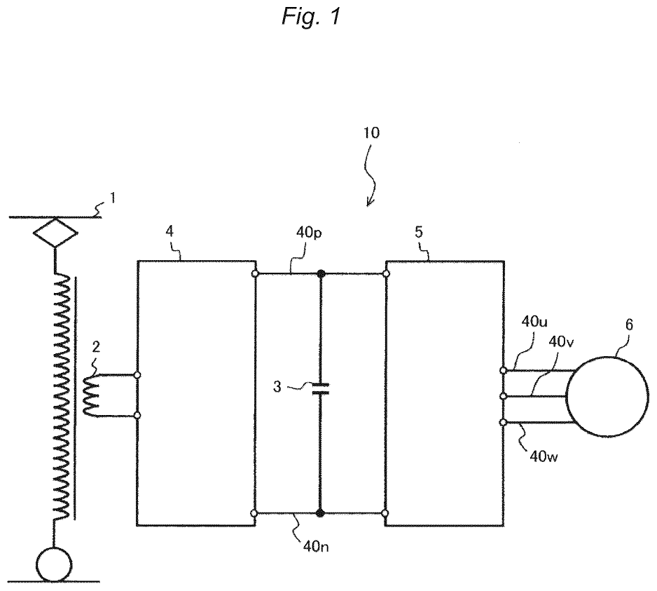

With reference to FIGS. 1 to 13, a power semiconductor module according to Embodiment 1 of the present invention will be described.

FIG. 1 is a circuit diagram of a main power conversion device 10 for a railway vehicle including a power semiconductor module according to the embodiment. The power semiconductor module according to the embodiment is an example of the application of the present invention to a direct water-cooled power semiconductor module mounted in the power conversion device.

As shown in FIG. 1, AC power supplied from the overhead line 1 is converted into DC power by a converter 4, which is a rectifying circuit. After the rectification by the converter 4, which constitutes the main power conversion device 10, the rectified DC power is smoothed by a smoothing capacitor 3 and applied to an inverter 5, where the power is converted back into AC power with a desired voltage and frequency. After the conversion, the three-phase AC power output from the inverter 5 becomes an output to an AC motor 6, and drives the AC motor 6 at a desired rotational speed.

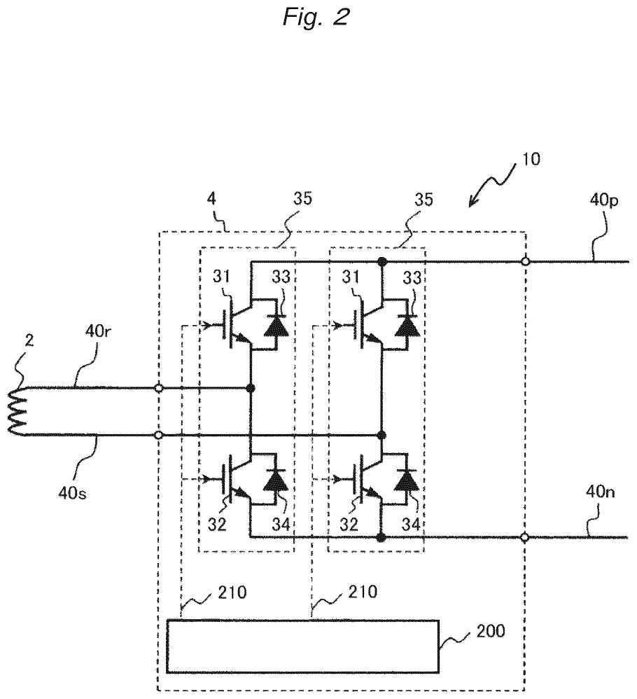

FIG. 2 is a circuit diagram of the converter 4 which constitutes the main power conversion device 10. As shown in FIG. 2, the converter 4 converts AC power from the overhead line 1 into DC power. The input AC power is supplied to the AC lines 40r and 40s of the converter 4 and is rectified by an upper arm switching element 31 and an upper arm rectifying element 33 and a lower arm switching element 32 and a lower arm rectifying element 34, provided for each phase.

According to the present embodiment, an IGBT (Insulated Gate Bipolar Transistor) is used as the switching element and a diode is used as the rectifying element, but other types of elements can be used. The switching elements 31 and 32 of the converter 4 are driven in response to a drive signal 210 from a control circuit 200.

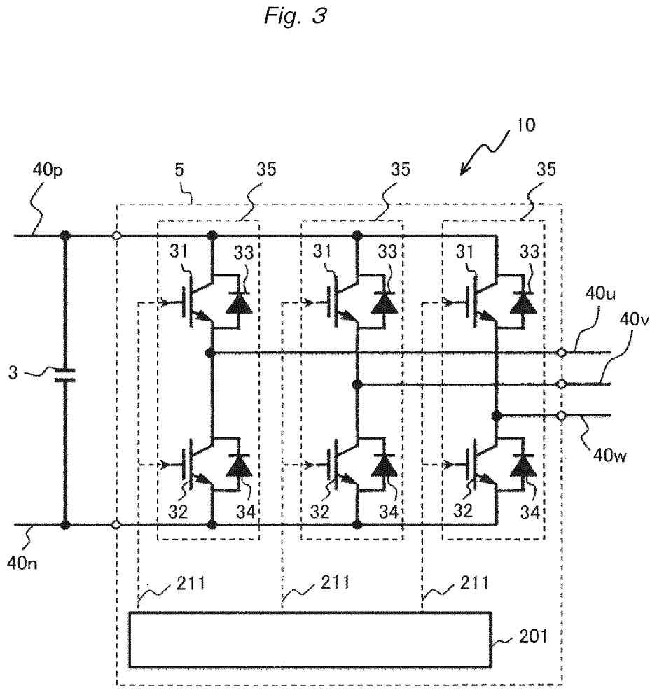

FIG. 3 is a circuit diagram of the inverter 5 which constitutes the main power conversion device 10. As shown in FIG. 3, the inverter 5 converts the DC power smoothed by the smoothing capacitor 3 into three-phase AC power.

The DC power converted by the converter 4 is converted into three-phase AC power by using the switching element 31 and the rectifying element 33 of the upper arm and the switching element 32 and the rectifying element 34 of the lower arm each provided in each phase, and the resulting power is output to AC lines 40u, 40v, and 40w. The switching elements 31 and 32 of the inverter 5 are driven in response to a drive signal 211 from a control circuit 201. In the converter 4 and the inverter 5, the power semiconductor module, which is provided with the switching elements 31 and 32 and the rectifying elements 33 and 34, generates heat and its temperature increases during the power conversion operation. In order to suppress the temperature rise, a cooling device is attached to the power semiconductor module for cooling.

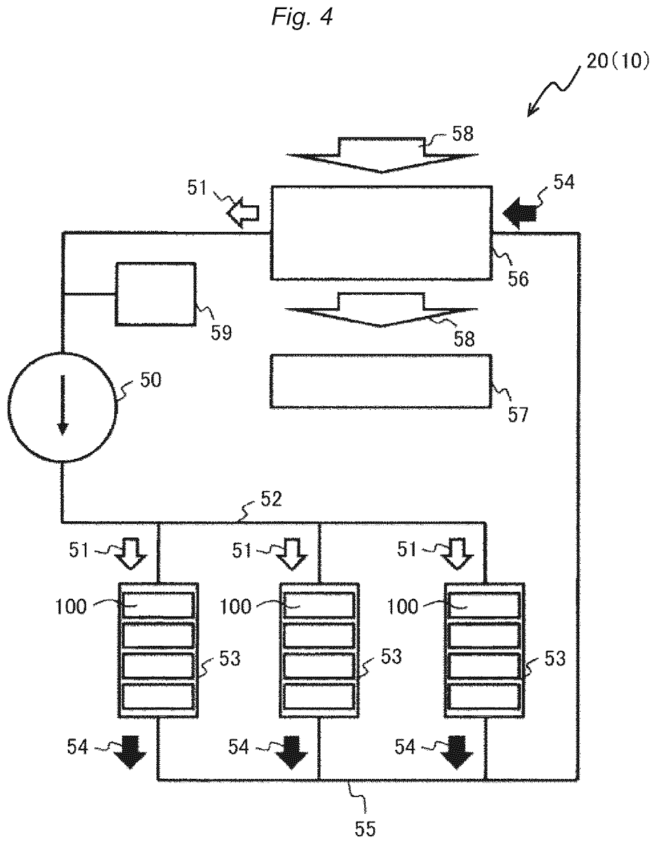

FIG. 4 is a diagram of the cooling system of a cooling device 20 which cools the converter 4 and the inverter 5. The cooling system of the cooling device 20 of the present embodiment ensures the stable operation of the main power conversion device 10 by removing the heat generated by the power semiconductor module 100 with circulating cooling water. Coolants such as water and ethylene glycol aqueous solutions are often used as cooling liquids, but other kinds of liquids may also be used.

In the present embodiment, three power units 53, each consisting of four parallel-connected power semiconductor modules 100, are arranged in parallel and cooled. The number of power semiconductor modules 100 connected in parallel or the number of power units 53 connected in parallel may be varied according to the rated output. Whether to use a parallel or series connection may be determined arbitrarily.

As shown in FIG. 4, low-temperature cooling water 51 (liquid coolant) discharged from a pump 50 is distributed to each power unit 53 by a low-temperature side distribution pipe 52. The distributed low-temperature cooling water 51 removes the heat generated by the power semiconductor modules 100 on each power unit 53, and becomes high-temperature cooling water 54 as its temperature increases. The high-temperature cooling water 54 is discharged from the power unit 53, then collected by a high-temperature side distribution pipe 55, and sent to a radiator 56.

The high-temperature cooling water 54 passing through the inside of the radiator 56 exchanges heat with cooling air 58 introduced by a fan 57, and becomes the low-temperature cooling water 51 as its temperature decreases. The volume change of the cooling water caused by the temperature variations in the cooling system is absorbed by an expansion tank 59. The low-temperature cooling water 51 discharged from the radiator 56 is pumped by the pump 50 and circulates through the cooling system.

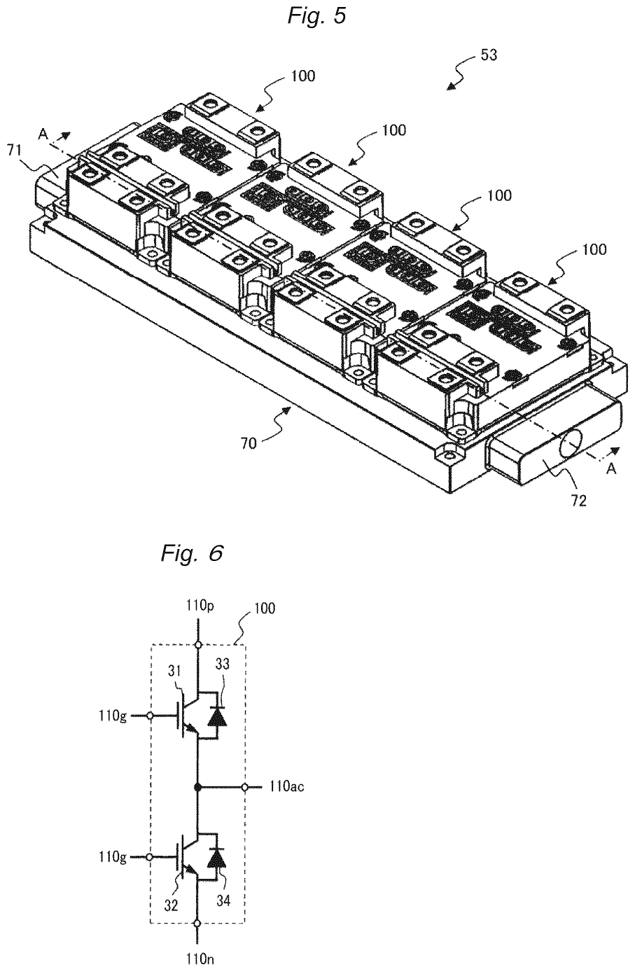

FIG. 5 is an external view of the power unit 53. As shown in FIG. 5, the power unit 53 includes four parallel-connected power semiconductor modules 100 and a water path forming body 70.

FIG. 6 is a circuit diagram of the power semiconductor module 100 used in the present embodiment. As shown in FIG. 6, the power semiconductor module 100 includes the switching elements 31 and 32 and the rectifying elements 33 and 34 mounted on an insulating substrate. The power semiconductor elements are connected to each other to constitute legs 35 shown in FIGS. 2 and 3. Further, a positive DC terminal 110p, a negative DC terminal 110n, an AC terminal 110ac, and a gate terminal 110g for controlling the on and off states of the switching elements are mounted on the insulating substrate.

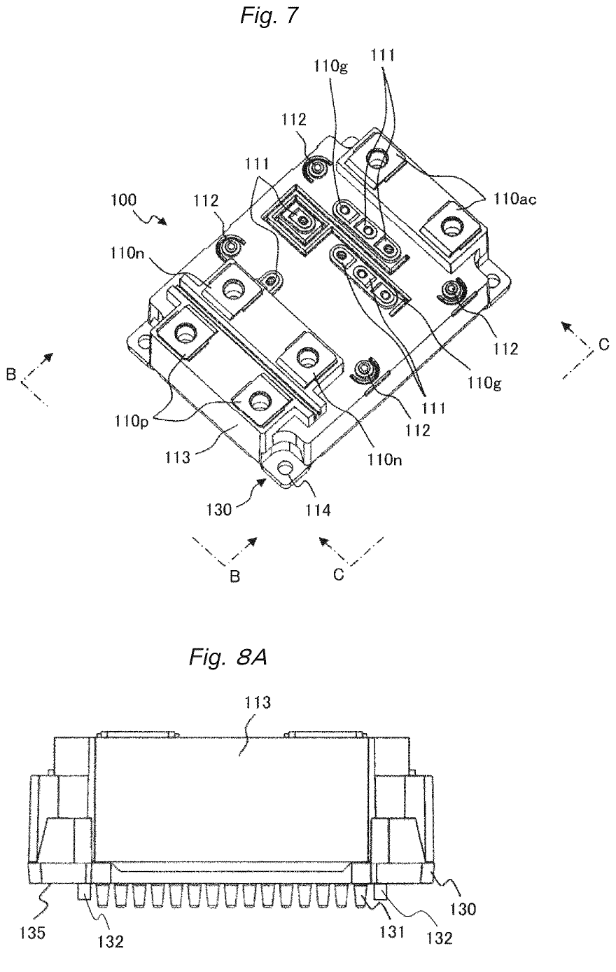

FIG. 7 is an external view of the power semiconductor module 100 used in the present embodiment. As shown in FIG. 7, the outer shell of the power semiconductor module 100 includes a base plate 130 for dissipating heat generated by a power semiconductor element 101 (reference numeral 101 in FIG. 9, which will be described later) therein to cooling water, and a housing 113 for protecting the power semiconductor element 101 and an insulating substrate 102 (reference numeral 102 in FIG. 9, which will be described later).

The power semiconductor module 100 includes a plurality of power semiconductor elements 101, the insulating substrate 102, and the single base plate 130, as will be described later with reference to FIG. 9. In the power semiconductor module 100, the power semiconductor element 101 is mounted on one surface of the insulating substrate 102, and the other surface of the insulating substrate 102 is bonded to the surface of the base plate 130. The other surface of the base plate 130 forms the bottom surface of the power semiconductor module 100 and is directly in contact with the low-temperature cooling water 51 (liquid coolant) for cooling.

Since the base plate 130 has the function of dissipating the heat generated by the power semiconductor elements 101 to the cooling water, the use of materials with a thermal conductivity greater than 100 W/mk, such as copper (Cu), aluminum (Al), AlSiC, and MgSiC, can be considered.

The base plate 130 has a through hole 114 for fixation to the water path forming body 70.

The housing 113 is formed using a resin material such as a polyphenylene sulfide resin. The positive DC terminal 110p and the negative DC terminal 110n are provided on one side of the power semiconductor module 100, the AC terminal 110ac is provided on the side opposite to the side where the DC terminals 110p and 110n are provided, and low-power terminals (the gate terminal 110g and a low-power electrode 111) are provided separately from high power terminals (the DC terminals 110p and 110n and the AC terminal 110ac).

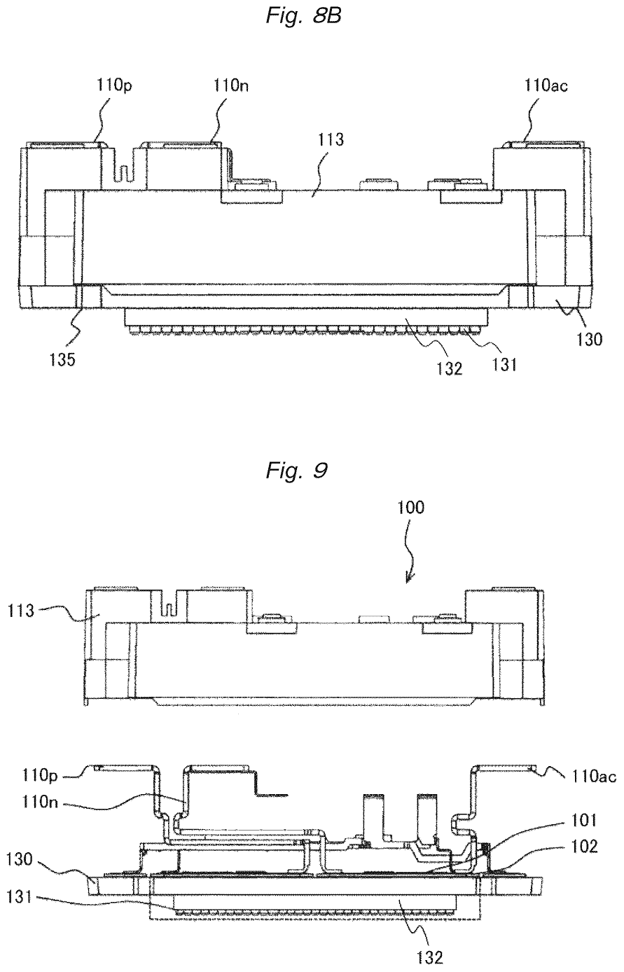

FIGS. 8A and 8B are side views of the power semiconductor module 100, FIG. 8A is a side view as viewed from the B-B direction in FIG. 7, and FIG. 8B is a side view as viewed from the C-C direction.

As shown in FIGS. 8A and 8B, a large number of pin fins (heat dissipation fins) 131 (for example, about 100 or more in total), which are fine cylindrical protrusions, are provided on the surface of the base plate 130 that abuts against the water path forming body 70 (the surface having the sealing part 135). There are two flat plate fins (plate-like fins) 132 that extend in the long-side direction to sandwich the region of the pin fins 131. The flat plate fins 132 have a height (length) from the base plate 130 that is lower (shorter) than the height (length) of the pin fins 131 from the base plate 130. The height of the flat plate fins 132 from the base plate 130 is uniform.

FIG. 9 is an exploded view of the power semiconductor module 100, which is shown as an exploded view of FIG. 8B. As shown in FIG. 9, the insulating substrate 102 on which the power semiconductor element 101 is mounted is bonded to the base plate 130 via a bonding material (not shown).

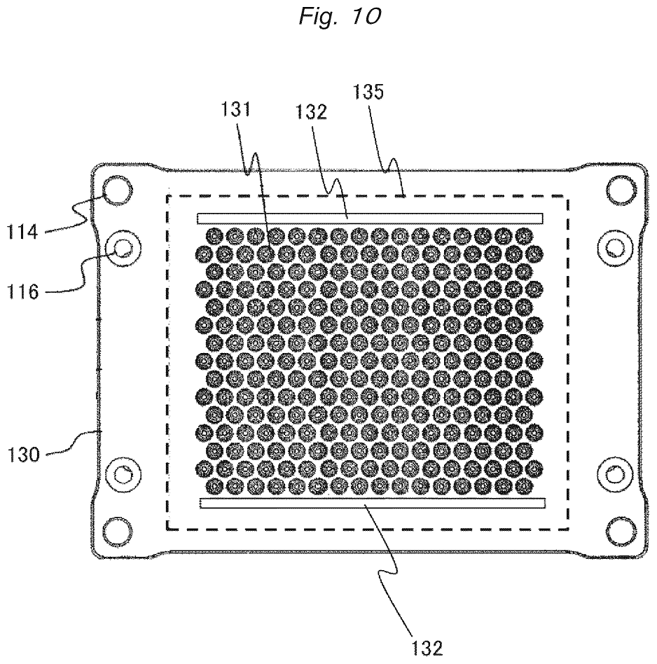

FIG. 10 is a plan view of the base plate 130 of the power semiconductor module 100 as viewed from the side of the water path forming body 70, i.e., a plan view of the heat dissipation fin forming surface of the base plate 130.

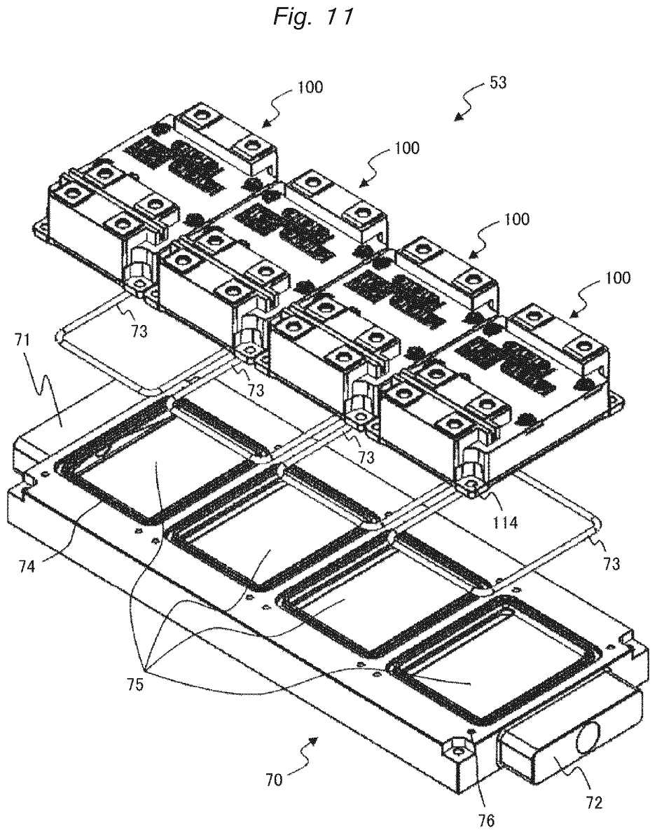

A large number of cylindrical pin fins 131 and a pair of flat plate fins 132 that extend in the long-side direction of the power semiconductor module 100 are formed on the base plate 130. There is a sealing part 135 shown by the dotted line. An O-ring (reference numeral 73 in FIG. 11, which will be described later) contacts this dotted line part to prevent leakage of the cooling water. The region of the pin fins 131 is sandwiched between the main surfaces of the flat plate fins 132.

The circular pin fins 131 may be formed to protrude from the base plate 130 by forging. Further, another pin-shaped member may be bonded to the base plate 130 by brazing or the like. Similarly, the flat plate fins 132 may be formed to protrude from the base plate 130 by forging. Further, a flat plate formed separately from the base plate 130 may be bonded to the base plate 130 by brazing, for example.

FIG. 11 is an exploded perspective view of the power unit 53 shown in FIG. 5. As shown in FIG. 11, the power unit 53 is formed by placing the power semiconductor modules 100 via the O-rings 73 to seal the openings 75 located on the upper surface of the water path forming body 70, and securing the power semiconductor modules 100 to the water path forming body 70 by passing bolts through the power semiconductor module fixing bolt holes 76. In the present embodiment, the O-ring 73 is used as the sealing member, but other sealing members may be used. By mounting the O-ring 73 and the power semiconductor module 100 from the upper surface, the O-ring 73 does not come off from an O-ring groove 74 during assembly, thereby improving the assembly efficiency.

FIG. 12 is a view showing the flow direction of the cooling water in the water path forming body 70. As shown in FIG. 12, the low-temperature cooling water 51 flows into the water path forming body 70 from a low-temperature side cooling water joint 71. Cooling water 60 (liquid coolant) in the water path forming body flows in a space (a space between sidewalls of a jacket) formed by the openings 75, the pin fins 131 and the flat plate fins 132 of the base plate 130, and directly cools the base plate 130. The cooling water 60 exchanges heat with the pin fins 131 and the flat plate fins 132, causing its temperature to rise, and becomes high-temperature cooling water 54, which is discharged from a high-temperature side cooling water joint 72.

As shown in FIG. 12, the low-temperature side cooling water joint 71 at the inlet of the water path forming body 70 and the high-temperature side cooling water joint 72 at the outlet have narrow flow paths. Meanwhile, an inter-adjacent module flow path 77, which runs between adjacent power semiconductor modules 100, has a width approximately equal to the long side of the opening 75.

In the structure shown in FIGS. 11 and 12, the main surfaces of the flat plate fins 132 are perpendicular to the direction of the flow of the cooling water 60 (liquid coolant).

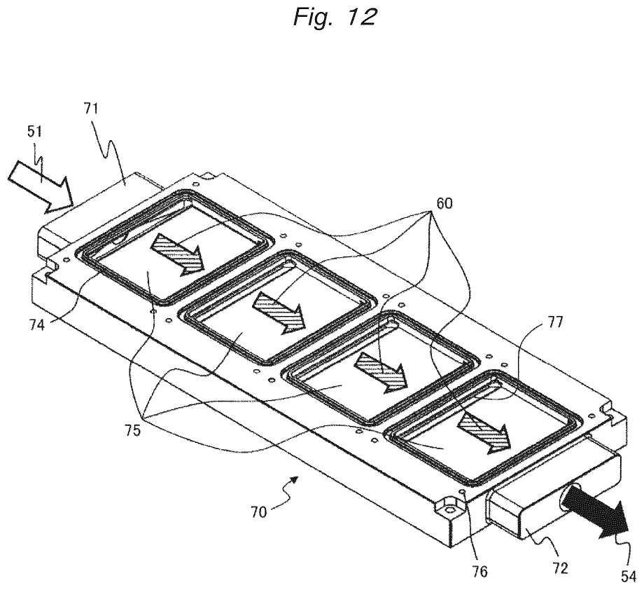

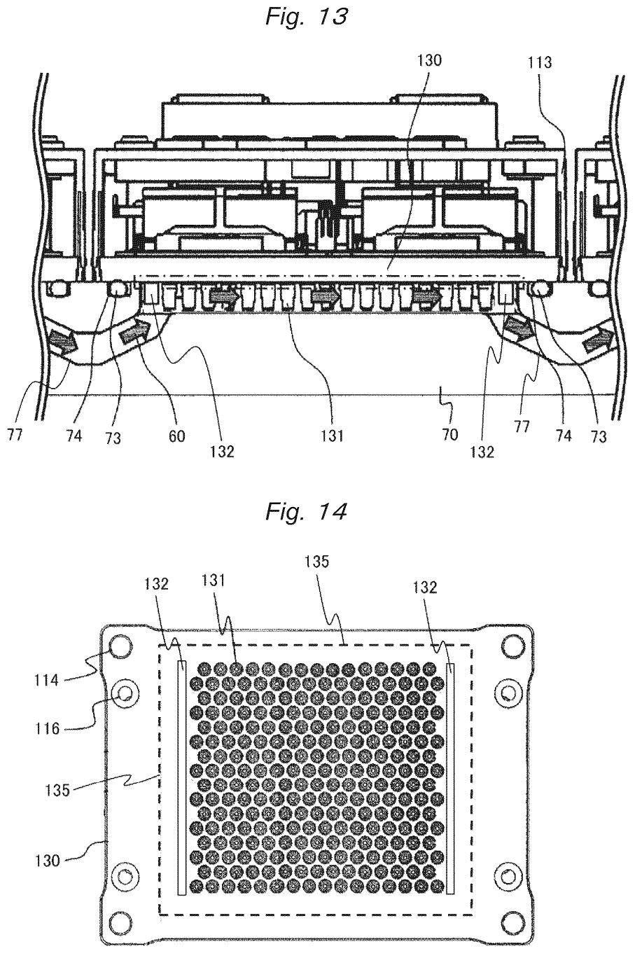

FIG. 13 is a cross-sectional view taken along line A-A in FIG. 5. As shown in FIG. 13, the flow path for the cooling water 60 runs under the flat plate fin 132, then passes through the region of the pin fins 131, and again passes under the flat plate fin 132 to be connected to the inter-adjacent module flow path 77, and has a greater depth than the region of the pin fins 131 in the inter-adjacent module flow path 77. As described above, the height of the flat plate fin 132 from the base plate 130 is lower than that of the pin fin 131.

The advantageous effects of the structure of the embodiment described above will be described.

As shown in FIG. 13, the effect of the height of the flat plate fin 132 from the base plate 130 being lower than that of the pin fin 131 will be described.

The cooling water 60 which enters the power unit 53 through the water path forming body 70 flows under the flat plate fins 132 lower than the pin fins 131, and therefore does not receive more than necessary flow path resistance, and the pressure loss increase can be minimized. In addition, when passing through the region of the power semiconductor module 100, the cooling water 60 passes under the flat plate fins 132 lower than the pin fins 131, and the pressure loss increase can be similarly minimized.

As shown in FIG. 10, the advantageous effect of the flat plate fins 132, which extend in the long-side direction of the base plate 130, being located near the sealing part 135 will be described.

Due to the pressure loss caused by the circulation of the cooling water, the base plate 130 is pressed by the cooling water 60 and deflects in the direction opposite to the extension of the pin fins 131. While the base plate 130 does not deform at the screw fastening parts at the four corners (the areas of the fastening through-holes 114), the deformation is greatest between the fastening parts. It is considered that water leakage occurs when the peripheral sealing part 135 exceeds a deformation threshold. Generally, the deflection of the base plate 130 is greater on the long-side than on the short-side, making water leakage more likely to occur on the long-side due to lower pressure loss.

In the present embodiment, since the flat plate fins 132 are located near the sealing part 135 on the long side of the base plate 130, the deformation of the base plate 130 on the long side due to pressure loss is suppressed, and the water pressure resistance can be increased.

As described above, according to the power semiconductor module of the present embodiment, by providing the flat plate fins 132 which extend in the long-side direction of the base plate 130 near the sealing part, necessary water pressure resistance can be ensured even if the base plate 130 is made thinner than the conventional cases. Therefore, the base plate 130 can be made thin, the path for dissipating the heat generated by the power semiconductor elements can be shortened, and the thermal resistance can be reduced. Further, since the flat plate fins 132 themselves also function as heat dissipation fins, the heat dissipation performance can be improved.

### Embodiment 2

With reference to FIG. 14, a power semiconductor module according to Embodiment 2 of the present invention will be described. FIG. 14 is a plan view of the base plate 130 of the power semiconductor module 100 as viewed from the side of the water path forming body 70, i.e., a plan view of the heat dissipation fin forming surface of the base plate 130.

As shown in FIG. 14, the power semiconductor module 100 of the present embodiment is different from Embodiment 1 (FIG. 10) in that the flat plate fins 132 which extend in the short-side direction of the base plate 130 are provided in the short-side direction of the region of the pin fins 131. The cooling water flows in the long-side direction of the power semiconductor module 100 rather than in the short-side direction. In addition, for power unit formation, the arrangement direction of the power semiconductor modules 100 is rotated by 90 degrees, forming the water path forming body 70 so that the short sides of the power semiconductor modules 100 are adjacent to each other. The other configurations are the same as those in Embodiment 1 (FIG. 10).

The advantageous effects of the structure of the present embodiment will be described.

The advantageous effect of the flat plate fins 132 being lower than the pin fins 131 in height from the base plate 130 will be described.

As described in connection with Embodiment 1 (FIG. 13), the cooling water 60 which has entered the power unit 53 through the water path forming body 70 flows under the flat plate fins 132 that are lower than the pin fins 131, and therefore does not receive more than necessary large flow path resistance, and the pressure loss increase can be minimized. In addition, when passing through the region of the power semiconductor module 100, the cooling water 60 passes under the flat plate fins 132 lower than the pin fins 131, and the pressure loss increase can be similarly minimized.

The advantageous effect of the flat plate fins 132, which extends in the short-side direction of the base plate 130, being located near the sealing part 135 will be described.

Although the deflection of the base plate 130 due to the pressure loss caused by the circulation of the cooling water is greater on the long sides of the base plate 130 than on the short sides of the base plate 130, thereby reducing the water pressure resistance on the long sides, while by applying a constraint to the power semiconductor module 100 to suppress the deformation on the long sides, the short sides of the base plate 130 become the next most likely location for water leakage. The base plate 130 is reinforced in the vicinity of the sealing part along its short sides by the flat plate fins 132 which extend in the short-side direction, so that the deformation on the short sides of the base plate 130 is suppressed and the water pressure resistance is improved.

According to the power semiconductor module of the present embodiment, by providing the flat plate fins 132 that extend in the short-side direction of the base plate 130 in the vicinity of the sealing part, necessary water pressure resistance can be ensured when the base plate 130 is made thinner than the conventional cases. Therefore, the base plate 130 can be made thin, the path for dissipating the heat generated by the power semiconductor elements can be shortened, and the thermal resistance can be reduced. Further, since the flat plate fins 132 themselves also function as heat dissipation fins, the heat dissipation performance can be improved.

### Embodiment 3

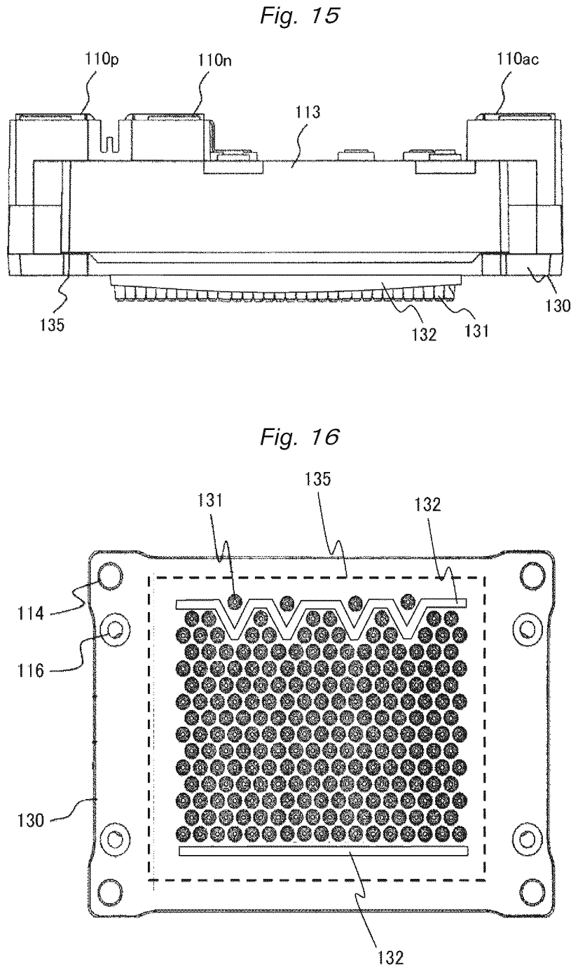

With reference to FIG. 15, a power semiconductor module according to Embodiment 3 of the present invention will be described. FIG. 15 is a side view of a power semiconductor module 100 of the embodiment, corresponding the C-C direction in FIG. 7.

The embodiment is different from Embodiment 1 (FIG. 8B) in that the height of the flat plate fins 132 which extend in the long-side direction of the power semiconductor module 100 from the base plate 130 is not uniform, but is highest in the vicinity of the mid point between the fastening points of the power semiconductor module 100. At least one of the two flat plate fins 132 has a structure with a high midpoint, and the other may be a flat plate fin with a uniform height. The other configurations are the same as those in Embodiment 1 (FIG. 8B).

The advantageous effects of the structure of the present embodiment will be described.

The effect of the flat plate fin 132 having a lower height (i.e., being thinner) from the base plate 130 than that of the pin fins 131 on the flow of the cooling water 60 and the cooling performance is the same as that in Embodiment 1. Also, the effect of the flat plate fins 132, which extend in the long-side direction of the power semiconductor module 100 (base plate 130), being located near the sealing part is the same as that in Embodiment 1.

The effect of the flat plate fin 132 having its greatest height at the center in the long-side direction of the power semiconductor module 100 as shown in FIG. 15 will be described.

The cooling water 60 entering from the low-temperature side cooling water joint 71 comes near the center in the long-side direction of the power semiconductor module 100. Simply by the presence of the region of the pin fins 131, the cooling water 60 does not end up making a short-circuiting flow only near the center of the power semiconductor module 100, but rather flows in a relatively uniform manner, though a slightly larger amount of water still tends to pass near the central part.

When the height near the center of the flat plate fin 132 on the side of the low-temperature side cooling water joint 71 is the highest in the power semiconductor module 100 near the low-temperature side cooling water joint 71, the flow of the cooling water 60 that would otherwise short-circuit through the central part of the power semiconductor module 100 is suppressed to some extent, and the flow is thereby redirected toward the right and left, resulting in a more uniform distribution, so that variations in the cooling performance among multiple chips within the power semiconductor module 100 are reduced.

The effect on the water pressure resistance of the flat plate fin 132 having its greatest height at the center in the long-side direction of the power semiconductor module 100, as shown in FIG. 15, will be described.

Although the water pressure resistance is improved by the presence of flat plate fin 132 with a uniform height in the vicinity of the sealing part in the long-side direction, which suppresses the deflection of the base plate 130 due to pressure loss, in the present embodiment, the flat plate fin has its greatest height, i.e., thickest, at the center of the long side, where deflection is most likely to occur, so that the deflection of the base plate 130 at the center of the long side is further suppressed and the water pressure resistance is further improved.

The effect on the cooling performance of the flat plate fin 132 having its greatest height at the center in the long-side direction of the power semiconductor module 100 as shown in FIG. 15 will be described.

By arranging the flat plate fin 132 that extends in the long-side direction of the power semiconductor module 100 in the vicinity of the sealing part, necessary water pressure resistance can be ensured when the base plate 130 is made thinner than the conventional case, while the water pressure resistance can be further improved by making the flat plate fin 132 higher (i.e., thicker) at the center of the long side where the deflection of the base plate 130 is likely to occur. As a result, the base plate 130 can be made thinner, the path for dissipating the heat generated by the power semiconductor elements can be shortened, and the thermal resistance can be reduced.

### Embodiment 4

With reference to FIG. 16, a power semiconductor module according to Embodiment 4 of the present invention will be described. FIG. 16 is a plan view of the base plate 130 of the power semiconductor module 100 as viewed from the side of the water path forming body 70, i.e., a plan view of the heat dissipation fin forming surface of the base plate 130.

The embodiment is different from Embodiment 1 (FIG. 10) in that one of two plate-like fins 132 that extend in the long-side direction of the base plate 130 is not a flat plate but is bent (has a bent part). The height of the plate-like fins 132 from the base plate 130 is uniform. Although the bent plate-like fin 132 has a straight part and a bent part by way of illustration, the fin may include a curved part. The other configurations are the same as those in Embodiment 1 (FIG. 10).

The advantageous effects of the structure of the present embodiment will be described.

The effect of the plate-like fins 132 having a lower height from the base plate 130 (i.e., being thinner) than the pin fins 131 on the flow of the cooling water 60 and the cooling performance is the same as that in Embodiment 1. Also, the effect of the plate-like fins 132, which extend in the long-side direction of the base plate 130, being located near the sealing part 135 is the same as that in Embodiment 1.

The effect of the bending of the plate-like fin 132 that extends in the long-side direction of the base plate 130 will be described.

Although flat plate fins that have a uniform width in the direction along the short side of the base plate 130 and extend linearly in the long-side direction can also suppress deformation at the center of the base plate 130 in the long-side direction, the meandering shape of the plate-like fin 132 formed by the bends increases the effective width in the direction along the short side of the base plate 130, thereby further enhancing the deformation-suppressing effect at the center in the long-side direction of the base plate 130 as compared to Embodiment 1 (FIG. 10). More specifically, the effect of improving the water pressure resistance is increased.

Since the water pressure resistance is improved, the base plate 130 can be made thinner, the path for dissipating the heat generated by the power semiconductor elements is shortened, and the thermal resistance can be reduced.

### Embodiment 5

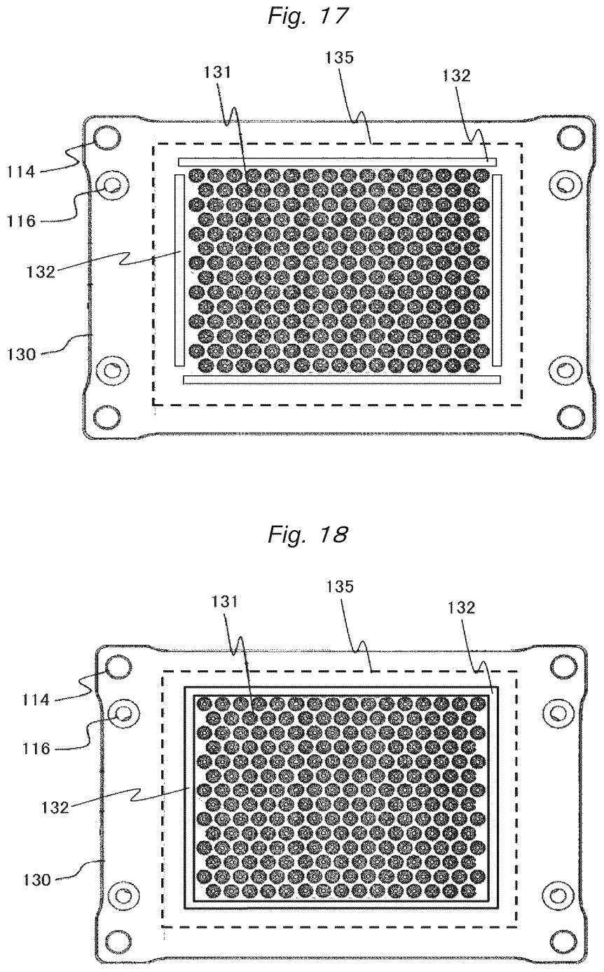

With reference to FIG. 17, a power semiconductor module according to Embodiment 5 of the present invention will be described. FIG. 17 is a plan view of the base plate 130 of the power semiconductor module 100 as viewed from the side of the water path forming body 70, i.e., a plan view of the heat dissipation fin forming surface of the base plate 130.

The embodiment is different from Embodiment 1 (FIG. 10) and Embodiment 2 (FIG. 14) in that there are both two flat plate fins 132 that extend in the long-side direction of the base plate 130 and two flat plate fins 132 that extend in the short-side direction of the base plate 130. The flat plate fins 132 are not connected to each other. The other configurations are the same as those of Embodiment 1 (FIG. 10) and Embodiment 2 (FIG. 14).

The advantageous effects of the structure of the present embodiment will be described.

The effect of the flat plate fins 132, which extend in the long-side direction of the base plate 130, having a lower height from the base plate 130 (i.e., being thinner) than the pin fins 131 on the flow of the cooling water 60 is the same as that in Embodiment 1. The effect of the flat plate fins 132, which extend in the short-side direction of the base plate 130, having a lower height from the base plate 130 (i.e., being thinner) than the pin fins 131 on the flow of the cooling water 60 and the cooling performance is the same as that in Embodiment 2.

Also in the present embodiment, since the flat plate fins 132 that extend in the long-side direction of the base plate 130 are located near the sealing part 135, the water pressure resistance on the long-side side can be improved. Further, since the flat plate fins 132 that extend in the short-side direction of the base plate 130 are located near the sealing part 135, the water pressure resistance on the short side can be improved.

Since the water pressure resistance is improved on both the long and short sides of the base plate 130, the base plate 130 can be made thinner, the path for dissipating the heat generated by the power semiconductor elements can be shortened, and the thermal resistance can be reduced.

### Embodiment 6

With reference to FIG. 18, a power semiconductor module according to Embodiment 6 of the present invention will be described. FIG. 18 is a plan view of the base plate 130 of the power semiconductor module 100 as viewed from the side of the water path forming body 70, i.e., a plan view of the heat dissipation fin forming surface of the base plate 130.

The embodiment is different from Embodiment 5 (FIG. 17) in that there are two flat plate fins 132 that extend in the long-side direction of the base plate 130 and two flat plate fins 132 that extend in the short-side direction of the base plate 130, and the flat plate fins 132 are connected to each other. More specifically, the flat plate fins 132 are arranged to surround the region of the pin fins 131. The other configurations are the same as those in Embodiment 5 (FIG. 17).

The advantageous effects of the structure of the present embodiment will be described.

The effect of the flat plate fins 132, which extend in the long-side direction of the base plate 130, having a lower height from the base plate 130 (i.e., being thinner) than the pin fins 131 on the flow of the cooling water 60 is the same as that in Embodiment 1. The effect of the flat plate fins 132, which extend in the short-side direction of the base plate 130, having a lower height from the base plate 130 (i.e., being thinner) than the pin fins 131 on the flow of the cooling water 60 and the cooling performance is the same as that in Embodiment 2.

Also in the present embodiment, since the flat plate fins 132 that extend in the long-side direction of the base plate 130 are located near the sealing part 135, the water pressure resistance on the long-side side can be improved. Further, since the flat plate fins 132 that extend in the short-side direction of the base plate 130 are located near the sealing part 135, the water pressure resistance on the short side can be improved. Further, since the flat plate fins 132 that extend in the long-side direction and the short-side direction are connected to each other, the base plate 130 has increased rigidity, and the water pressure resistance is further increased.

Since the water pressure resistance is further improved on both the long and short sides of the base plate 130 than in Embodiment 5, the base plate 130 can be made thinner, the path for dissipating the heat generated by the power semiconductor elements can be shortened, and the thermal resistance can be reduced.

### Embodiment 7

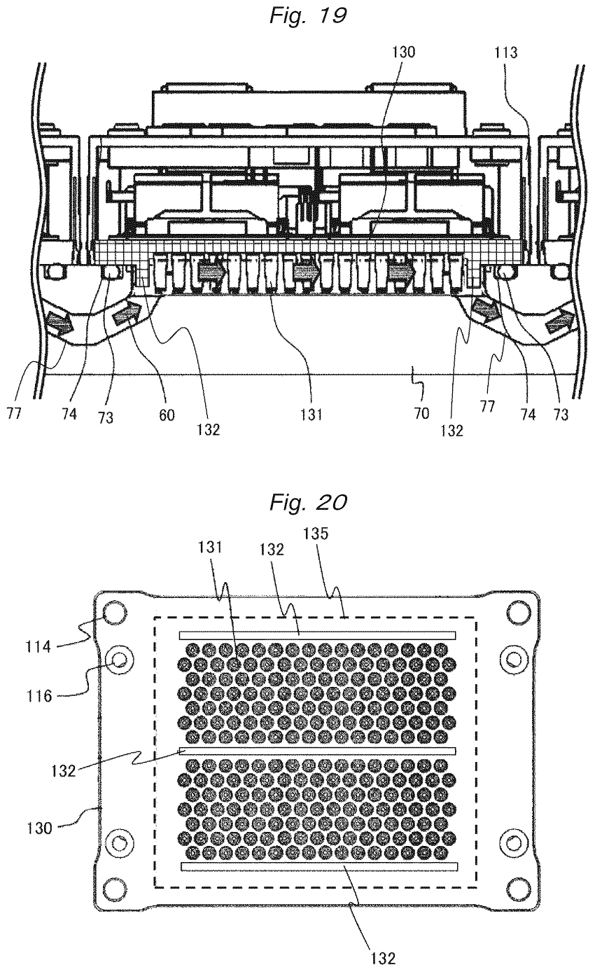

With reference to FIG. 19, a power semiconductor module according to Embodiment 7 of the present invention will be described. FIG. 19 is a cross-sectional view of a power unit according to the embodiment and corresponds to FIG. 13 in Embodiment 1.

The embodiment is different from Embodiment 1 (FIG. 13) in that the thickness of the base plate 130 outside the region of the pin fins 131 is thicker than that of the base plate 130 in the region of the pin fins 131. Here, the base plate 130 in the region where the flat plate fins 132 are present is also thick. Further, the flat plate fins 132 that extend in the long-side direction of the base plate 130 and the base plate 130 have two thick parts near the sealing part. The other configurations are the same as those in Embodiment 1 (FIG. 13).

The advantageous effects of the structure of the present embodiment will be described.

Although the water pressure resistance is improved because the base plate 130 has its long sides reinforced by the flat plate fins 132 that extend in the long-side direction of the base plate 130, the water pressure resistance at the center in the long-side direction and the center in the short-side direction of the base plate 130 is further increased because the base plate 130 is thicker outside the region of the pin fins 131 according to the present embodiment.

Since the water pressure resistance is further improved on both the long and short sides of the base plate 130 than in Embodiment 1, the base plate 130 can be made thinner, the path for dissipating the heat generated by the power semiconductor elements can be shortened, and the thermal resistance can be reduced.

### Embodiment 8

With reference to FIG. 19, a power semiconductor module according to Embodiment 8 of the present invention will be described. FIG. 19 is a cross-sectional view of a power unit according to the embodiment and corresponds to FIG. 13 in Embodiment 1.

The embodiment is different from Embodiment 7 in that there are both two flat plate fins 132 that extend in the long-side direction of the base plate 130 and two flat plate fins 132 that extend in the short-side direction of the base plate 130. In both the long-side and short-side directions of the base plate 130, the thickness of the base plate 130 outside the region of the pin fins 131 is greater than that of the base plate 130 in the region of the pin fins 131. The other configurations of the embodiment are the same as those in Embodiment 7.

The advantageous effects of the structure of the present embodiment will be described.

While the long and short sides of the base plate 130 are reinforced by the flat plate fins 132 that extend in the long-side and short-side directions of the base plate 130, thereby improving the water pressure resistance, in the present embodiment, the base plate 130 is thicker outside the region of the pin fins 131 according to the embodiment, so that the water pressure resistance at the center in the long-side and short-side directions of the base plate 130 is further increased.

Since the water pressure resistance is improved on both the long and short sides of the base plate 130 as compared with those in Embodiment 1 and Embodiment 7, the base plate 130 can be made thinner, the path for dissipating the heat generated by the power semiconductor elements can be shortened, and the thermal resistance can be reduced.

### Embodiment 9

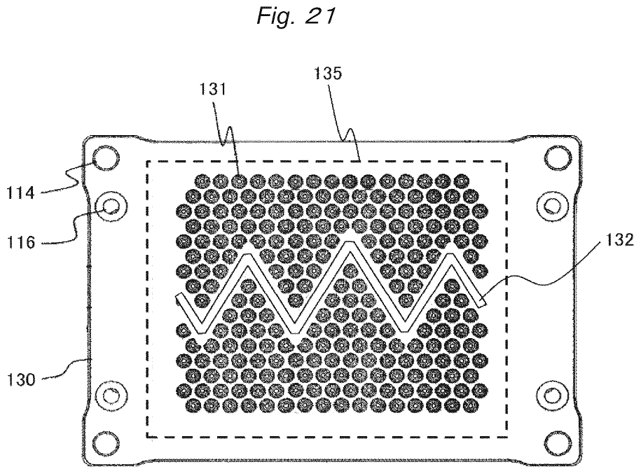

With reference to FIG. 20, a power semiconductor module according to Embodiment 9 of the present invention will be described. FIG. 20 is a plan view of the base plate 130 of the power semiconductor module 100 as viewed from the side of the water path forming body 70, i.e., a plan view of the heat dissipation fin forming surface of the base plate 130.

The embodiment is different from Embodiment 1 (FIG. 10) in that there are flat plate fins 132 that extend in the long-side direction also at the center of the base plate 130, and there are three flat plate fins 132 in total. The other configurations are the same as those in Embodiment 1 (FIG. 10).

The advantageous effects of the structure of the present embodiment will be described.

In Embodiment 1 (FIG. 10), two flat plate fins 132 that extend in the long-side direction of the base plate 130 are provided to sandwich the region of the pin fins 131, but in the present embodiment, a flat plate fin 132 is additionally provided at the center of the base plate 130. The addition of the flat plate fin 132 to the central part of the base plate 130 reduces the deflection of the central part of the base plate 130 due to the water pressure caused by the pressure loss and also reduces the deflection of the sealing part, thereby improving the water pressure resistance at the center of the long side as compared to Embodiment 1.

Since the water pressure resistance on the long side of the base plate 130 is improved, the base plate 130 can be made thinner, the path for dissipating the heat generated by the power semiconductor elements can be shortened, and the thermal resistance can be reduced.

Although an increase in pressure loss due to the addition of the flat plate fin 132 at the central part of the base plate 130 as compared to Embodiment 1 (FIG. 10) may be of concern, the cooling water 60 passes under the flat plate fins 132, which are lower than the pin fins 131, so that the flow path resistance does not become excessively large, and the increase in pressure loss can be minimized.

### Embodiment 10

With reference to FIG. 21, a power semiconductor module according to Embodiment 10 of the present invention will be described. FIG. 21 is a plan view of the base plate 130 of the power semiconductor module 100 as viewed from the side of the water path forming body 70, i.e., a plan view of the heat dissipation fin forming surface of the base plate 130.

The embodiment is different from Embodiment 1 (FIG. 10) in that the plate-like fin 132 is provided in the vicinity of the center of the base plate 130 and is bent. The other configurations are the same as those in Embodiment 1 (FIG. 10).

The advantageous effects of the structure of the present embodiment will be described.

In Embodiment 1 (FIG. 10), two flat plate fins 132 that extend in the long-side direction of the base plate 130 are provided to sandwich the region of the pin fins 131, but in the present embodiment, a single plate-like fin 132 is provided at the center of the base plate 130. Since the plate-like fin 132 is not straight but bent, this is effectively equivalent to providing a wider plate-like fin in the short-side direction. As a result, the deflection of the base plate 130 at the central part due to water pressure caused by pressure loss is reduced, and the deflection of the sealing part 135 is also reduced, so that the water pressure resistance at the center of the long side is improved.

Since the water pressure resistance on the long side of the base plate 130 is improved, the base plate 130 can be made thinner, the path for dissipating the heat generated by the power semiconductor elements can be shortened, and the thermal resistance can be reduced.

Although an increase in pressure loss due to the presence of the plate-like fin 132 at the central part of the base plate 130 may be of concern, the cooling water 60 passes under the plate like fin 132, which is lower than the pin fins 131, so that the flow path resistance does not become excessively large, and the increase in pressure loss can be minimized.

While the above embodiments have been described by way of illustration with reference to a main power conversion device for railway vehicles, the present invention is also applicable to power conversion devices for automobiles and trucks, power conversion devices for ships and aircraft, industrial power conversion devices used as motor controllers for driving factory equipment, and household power conversion devices used in solar power generation systems for household use or in motor controllers for driving home appliances.

The present invention is not limited to the embodiments described above, and various modifications are encompassed by the present invention. For example, the above-described embodiments are provided in detail for the purpose of facilitating understanding of the present invention, and the invention is not necessarily limited to configurations including all of the described components. It is also possible to replace part of the configuration of one embodiment with that of another embodiment, or to add one or more configurations of one embodiment to another. It is also possible to add to, remove from, or replace part of the configuration of each embodiment with other configurations.

### REFERENCE SIGNS LIST

1 Overhead line
2 Transformer
3 Smoothing capacitor
4 Converter
5 Inverter
6 AC motor
10 Main power conversion device
20 Cooling device
31 Upper arm switching element
32 Lower arm switching element
33 Upper arm rectifying element
34 Lower arm rectifying element
35 Leg
40p, 40n DC line
40r, 40s, 40u, 40v, 40w AC line
50 Pump
51 Low-temperature cooling water (liquid coolant)
52 Low-temperature side distribution pipe
53 Power unit
54 High-temperature cooling water
55 High-temperature side distribution pipe
56 Radiator
57 Fan
58 Cooling air
59 Expansion tank
60 Cooling water (liquid coolant) in water path forming body
70 Water path forming body
71 Low-temperature side cooling water joint
72 High-temperature side cooling water joint
73 O-ring
74 O-ring groove
75 Opening
76 Power semiconductor module fixing bolt hole
77 Inter-adjacent module flow path
100 Power semiconductor module
101 Power semiconductor element
102 Insulating substrate
110p Positive DC terminal
110n Negative DC terminal
110ac AC terminal
110g Gate terminal
111 Low power electrode
112 Gate drive substrate fixing screw hole
113 Housing
114 Power semiconductor module fixing through hole
130 Base plate
131 Pin-fin (heat dissipation fin)
132 Flat-plate fin (plate-like fin)
135 Sealing part
200 Converter control circuit
201 Inverter control circuit
210 Drive signal
211 Drive signal

1. A direct water-cooled semiconductor device in which a surface of a base plate opposite to a semiconductor element mounting surface is cooled by a coolant, the semiconductor device comprising:
the base plate;
a semiconductor module mounted on a first surface of the base plate; and
a pin fin and a plate-like fin attached to a second surface of the base plate opposite to the first surface,
the plate-like fin having a length from the second surface which is shorter than that of the pin fin from the second surface.

2. The semiconductor device according to claim 1, wherein
a region on the second surface where the pin fin is provided is located in a region sandwiched between at least two of the plate-like fins.

3. The semiconductor device according to claim 2, wherein
the region where the pin fin is provided is located in a region sandwiched between main surfaces of at least two of the plate-like fins.

4. The semiconductor device according to claim 2, wherein
the region where the pin fin is provided is located in a region sandwiched between two of the plate-like fins provided to extend in a long-side direction of the base plate and two of the plate-like fins provided to extend in a short-side direction of the base plate.

5. The semiconductor device according to claim 4, wherein
the two of the plate-like fins provided to extend in the long-side direction and the two of the plate-like fins provided to extend in the short-side direction are connected to each other, and
a region where the pin fins are provided is located in a region surrounded by the plate-like fins connected to each other.

6. The semiconductor device according to claim 1, wherein
the plate-like fin is provided to extend in at least one of a long-side direction and a short-side direction of the base plate, and
the plate-like fin has a length at a center in its extending direction that is longer than that at an end thereof.

7. The semiconductor device according to claim 1, wherein
the base plate has a greater thickness outside a region where the pin fin is provided than in a region where the pin fin is provided.

8. The semiconductor device according to claim 1, wherein
a main surface of the plate-like fin is perpendicular to a water flow direction of the coolant.

9. The semiconductor device according to claim 1, wherein
wherein the plate-like fin has a bent part.

10. The semiconductor device according to claim 1, wherein
the base plate has a sealing part connected to a water path forming body to form a flow path for the coolant,
wherein the plate-like fin is provided near the sealing part.
